(19) United States
(12) Patent Application Publication
(10) Pub. No.: US 2018/0175326 A1
(43) Pub. Date: Jun. 21, 2018

(54) LIGHT EMITTING DEVICE

(71) Applicant: Industrial Technology Research Institute, Hsinchu (TW)

(72) Inventors: Yi-Hsiang Huang, Changhua County (TW); Yu-Tang Tsai, New Taipei City (TW); Kuan-Ting Chen, Yunlin County (TW)

(73) Assignee: Industrial Technology Research Institute, Hsinchu (TW)

(21) Appl. No.: 15/464,361

(22) Filed: Mar. 21, 2017

(30) Foreign Application Priority Data
Dec. 16, 2016 (TW) 105141726

(51) Int. Cl. H01L 51/52; H01L 27/32

(52) U.S. Cl. CPC H01L 51/5275; H01L 27/3244; H01L 2251/5315; H01L 51/5234; H01L 2251/558; H01L 51/5206

(57) ABSTRACT

A light emitting device includes a first electrode, a second electrode, an organic layer and a conductive layer. The organic layer is disposed between the first electrode and the second electrode. The conductive layer is disposed between the organic layer and the first electrode. A refractive index of the conductive layer is lower than a refractive index of the organic layer in a visible light wavelength, so that an energy radiated by a light emitted by the organic layer through the first electrode is less than an energy radiated by the light emitted by the organic layer through the second electrode.

### CROSS-REFERENCE TO RELATED APPLICATION

This application claims the priority benefit of Taiwan application serial no. 105141726, filed on Dec. 16, 2016. The entirety of the above-mentioned patent application is hereby incorporated by reference herein and made a part of this specification.

### BACKGROUND

### Technical Field

The disclosure relates to a light emitting device.

### Description of Related Art

Generally speaking, an organic light emitting diode (OLED) is mainly composed of a metal anode, a transparent cathode, and an organic light emitting layer that is disposed between the metal anode and the transparent cathode. When electricity is applied to the metal anode and the transparent cathode, electron-hole pairs can generate excitons in the organic light emitting layer of the organic layer. As a result, the organic light emitting layer performs a light emitting mechanism in which different colors are generated according to the nature of layer materials so as to achieve an effect of light-emitting display.

Common OLED modes can be divided into the following three kinds: (1) a radiation mode, in which part of the light emitted by the organic light emitting layer is projected to the outside and is out-coupled into air so as to serve as useful light; (2) a waveguided mode, in which the light is waveguided among the organic light emitting layer, the metal anode and the transparent cathode, and is then confined between the metal anode and the transparent cathode; (3) a surface plasmon polariton (SPP) mode, which indicates a light energy loss caused by electric dipole oscillations between excitons and an interface of the metal anode, i.e. the light is absorbed by the metal. The radiation mode of conventional top-emitting OLEDs is about 30% to 40%, and the SPP mode is about 40% to 50%. In other words, efficiency of conventional top-emitting OLEDs is lower caused by SPP, meaning that the efficiency of conventional top-emitting OLEDs is not high.

### SUMMARY

In an embodiment of this disclosure, the light emitting device includes a first electrode, a second electrode, an organic layer, and a conductive layer. The organic layer is disposed between the first electrode and the second electrode. The conductive layer is disposed between the organic layer and the first electrode, and wherein a refractive index of the conductive layer is lower than a refractive index of the organic layer in a visible light wavelength, so that an energy radiated by a light emitted by the organic layer through the first electrode is less than an energy radiated by the light emitted by the organic layer through the second electrode.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 illustrates a schematic sectional view of a light emitting device according to an embodiment of the disclosure.

FIG. 2 illustrates a schematic sectional view of a light emitting device according to another embodiment of the disclosure.

FIG. 3 illustrates a schematic sectional view of a light emitting device according to another embodiment of the disclosure.

FIG. 4 illustrates a schematic sectional view of a light emitting device according to another embodiment of the disclosure.

FIG. 5 illustrates a schematic sectional view of a light emitting device according to another embodiment of the disclosure.

FIG. 6 illustrates a schematic sectional view of a light emitting device according to another embodiment of the disclosure.

### DESCRIPTION OF THE EMBODIMENTS

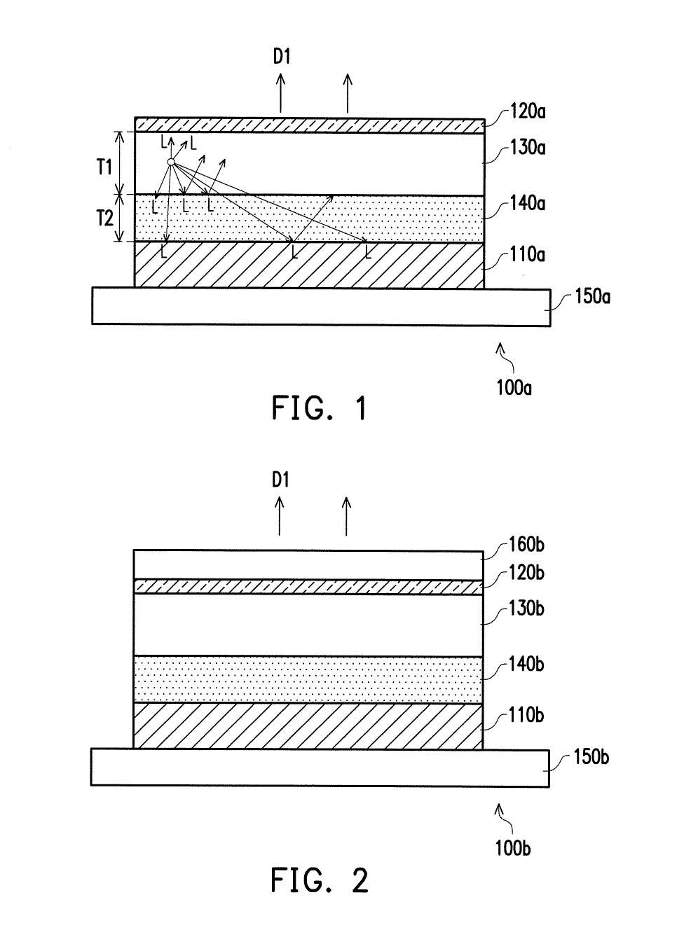

FIG. 1 illustrates a schematic sectional view of a light emitting device according to an embodiment of the disclosure. Please refer to FIG. 1, in this embodiment, a light emitting device 100a includes a first electrode 110a, a second electrode 120a, an organic layer 130a, and a conductive layer 140a. The organic layer 130a is disposed between the first electrode 110a and the second electrode 120a. The conductive layer 140a is disposed between the organic layer 130a and the first electrode 110a. Wherein a refractive index of the conductive layer 140a is lower than a refractive index of the organic layer 130a in a visible light wavelength, so that an energy radiated by a light L emitted by the organic layer 130a through the first electrode 110a is less than an energy radiated by the light L emitted by the organic layer 130a through the second electrode 120a.

In this embodiment, the light emitting device 100a further includes a substrate 150a, on which the first electrode 110a, the second electrode 120a, the organic layer 130a, and the conductive layer 140a are disposed. As shown in FIG. 1, the first electrode 110a, the conductive layer 140a, the organic layer 130a, and the second electrode 120a are sequentially stacked on the substrate 150a. The substrate 150a is, for example, a carrier substrate or an active element array substrate, but the embodiment is not limited thereto.

Regarding material selection, materials of the first electrode 110a and the second electrode 120a are, for example, metal, transparent conductive materials, or a combination thereof. Refractive indices of the first electrode 110a and the second electrode 120a are, for example, in a range of 0.1 to 5.0, in the visible wavelength. Here, metal is used to exemplify the material of the first electrode 110a, and a combination of metal and a transparent conductive material is used to exemplify the material of the second electrode 120a. Therefore, in this embodiment, the first electrode 110a is viewed as a reflective metal layer and the second electrode 120a is viewed as a transreflective conductive layer. In addition, a material of the conductive layer 140a is, for example, a transparent conductive compound such as a transparent conductive organic compound, a transparent conductive inorganic compound or a combination thereof, and the conductive layer 140a is formed by methods such as chemical vapor deposition, physical deposition, thermal evaporation, screen printing, coating, printing, sputtering, or electroplating. Here, an oblique film forming method may also be employed to mix air into the structure or to substitute gas for liquid in the gel (i.e. aerogel), so as to lower the refractive index of the conductive layer 140a.

In this embodiment, the organic layer 130a at least includes an organic light emitting layer. To further enhance extraction efficiency of the light emitting device 100a, in an embodiment that is not shown, the organic layer further includes an electron transport layer and a hole transport layer. Here the electron transport layer is composed of an electron transport material and is, for example, disposed between the organic layer 130a and the second electrode 120a, and the hole transport layer is composed of a hole transport material and is, for example, disposed between the organic layer 130a and the first electrode 110a. In addition, the organic layer may further include a hole injection layer. Here the hole injection layer is composed of a hole injection material and is, for example, disposed between the first electrode 110a and the hole transport layer. In another embodiment that is not shown, in the organic layer is further disposed an electron injection layer between the second electrode 120a and the electron transport layer. However, it is worth mentioning that the hole injection layer, the hole transport layer, the electron transport layer, and the electron injection layer are optional configurations and may also not be present in the light emitting device 100a.

Furthermore, regarding selection of refractive indices and thickness, in this embodiment, the refractive index of the first electrode 110a is, for example, in a range of 0.1 to 5.0, in the visible wavelength. The refractive index of the organic layer 130a is, for example, in a range of 1.2 to 2.5 in the visible light wavelength. The refractive index of the conductive layer 140a is, for example, in a range of 1.1 to 1.7 in the visible light wavelength. Here, a thickness T2 of the conductive layer 140a is, for example, in a range of 30 nanometers to 200 nanometers.

Moreover, in simulation, the light emitting device 100a of this embodiment has a radiation mode of approximately 40%, a waveguided mode of 30%, and a SPP mode of 30%. Comparing the traditional device without the 140a, the radiation energy is larger than the SPP energy. In other words, in this embodiment, extraction efficiency of the light emitting device 100a is higher than a traditional device without the 140a. To put it in another way, the light emitting device 100a of this embodiment has favorable light extraction efficiency.

In this embodiment, the light emitting device 100a is provided with the conductive layer 140a, and here the refractive index of the conductive layer 140a (for example, in a range of 1.1 to 1.7) is lower than the refractive index of the organic layer 130a (for example, may be in a range of 1.7 to 1.9) in the visible light wavelength. As a result, it is easy for the light L emitted by the organic layer 130a to have reflection at an interface between the organic layer 130a and the conductive layer 140a, so numerous light L would transfer to the second electrode 120a (i.e. a light emitting direction D1 in FIG. 1). In other words, the light L emitted by the organic layer 130a radiates more energy through the second electrode 120a, and the light emitting device 100a is viewed as a top-emitting light emitting device. On the other hand, because of the interface reflection, the light L emitted by the organic layer 130a that enters into the conductive layer 140a is lessened, so as to effectively reduce a light energy loss that occurs between excitons and an interface of the first electrode 110a. That is, the light L emitted by the organic layer 130a radiates less energy through from the first electrode 110a. In other words, an energy radiated by the light L emitted by the organic layer 130a through the first electrode 110a is less than an energy radiated by the light L emitted by the organic layer 130a through the second electrode 120a. To put it in another way, in this embodiment, light extraction efficiency of the light emitting device 100a is higher than a light energy loss caused by SPP. So, the light emitting device 100a of this embodiment has favorable light extraction efficiency.

It should be noted that reference numerals and partial contents in the foregoing embodiment are used in the following embodiments, and here the same numerals indicate identical or similar components while repeated description of the same technical contents is omitted. Please refer to the foregoing embodiment for the omitted description, which will not be repeated in the following embodiments.

FIG. 2 illustrates a schematic sectional view of a light emitting device according to another embodiment of the disclosure. Please refer to FIG. 1 and FIG. 2 simultaneously. A light emitting device 100b in this embodiment is similar to the light emitting device 100a of FIG. 1. The difference between the two devices is that the light emitting device 100b of this embodiment further includes a cover layer 160b, and a second electrode 120b is disposed between the cover layer 160b and an organic layer 130b. That is, a first electrode 110b, a conductive layer 140b, the organic layer 130b, the second electrode 120b, and the cover layer 160b are sequentially stacked on a substrate 150b. A material of the cover layer 160b is, for example, an organic material that has a high refractive index and is conducive to deposition, and the cover layer 160b effectively protects the second electrode 120b.

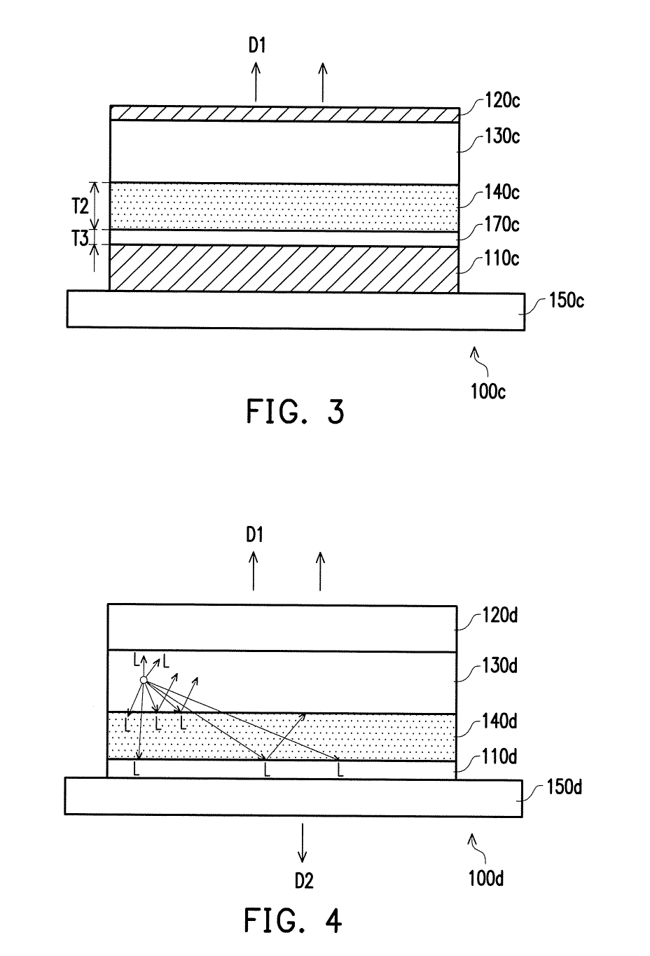

FIG. 3 illustrates a schematic sectional view of a light emitting device according to another embodiment of the disclosure. Please refer to FIG. 1 and FIG. 3 simultaneously. A light emitting device 100c in this embodiment is similar to the light emitting device 100a of FIG. 1. The difference between the two devices is that the light emitting device 100c of this embodiment further includes a buffer layer 170c, and the buffer layer 170c is disposed between a first electrode 110c and a conductive layer 140c. That is, the first electrode 110c, the buffer layer 170c, the conductive layer 140c, an organic layer 130c, and a second electrode 120c are sequentially stacked on a substrate 150c. Here, the buffer layer 170c is used to overcome surface roughness of the first electrode 110c so that effects such as planarization, conductivity enhancement, and carrier injection facilitation are achieved. A material of the buffer layer 170c is, for example, a transparent conductive material such as ITO. A thickness T2 of the conductive layer 140c and a thickness T3 of the buffer layer 170c satisfy the following formula:

$${D}_{low} = \frac{( 2 m + 1 ) λ}{4 {n}_{low}} - {\sum }_{i} {n}_{i} {d}_{i} - \vert \frac{{∅}_{metal}}{4 π} λ \vert \pm 20 nm , \\ wherein m = 0 , 1 , 2 , …$$

wherein,

$${∅}_{metal} = arctan \frac{2 {n}_{s} {k}_{metal}}{( {n}_{{s}^{2}} - {n}_{{metal}^{2}} - {k}_{{metal}^{2}} )}$$

Here, D_{low} is the thickness T2 of the conductive layer 140c, n_{low} is a refractive index of the conductive layer 140c, λ is an adopted wavelength (of a spectral peak), nᵢ is a refractive index of the buffer layer 170c, di is the thickness T3 of the buffer layer 170c, nₛ is a refractive index of a dielectric layer in contact with the first electrode 110c (such as the buffer layer 170c) before a light emitted by the light emitting device (such as a light emitted by the organic layer 130c) enters into the first electrode 110c, nₘₑₜₐₗ is a refractive index of the first electrode 110c, and kₘₑₜₐₗ is an extinction coefficient of the first electrode 110c. By the above formula, it is able to obtain the thickness T2 of the conductive layer 140c.

In an embodiment not provided with a buffer layer, the above formula is modified as follows:

$${D}_{low} = \frac{( 2 m + 1 ) λ}{4 {n}_{low}} - \vert \frac{{∅}_{metal}}{4 π} λ \vert \pm 20 nm , \\ wherein m = 0 , 1 , 2 , …$$

wherein,

$${∅}_{metal} = arctan \frac{2 {n}_{s} {k}_{metal}}{( {n}_{{s}^{2}} - {n}_{{metal}^{2}} - {k}_{{metal}^{2}} )}$$

It is also able to obtain a thickness of a conductive layer by the above formula.

FIG. 4 illustrates a schematic sectional view of a light emitting device according to another embodiment of the disclosure. Please refer to FIG. 1 and FIG. 4 simultaneously. A light emitting device 100d in this embodiment is similar to the light emitting device 100a of FIG. 1. The difference between the two devices is that in this embodiment a first electrode 110d and a second electrode 120d are both transparent conductive materials. That is, the first electrode 110d and the second electrode 120d are viewed as transparent electrodes. Here, a substrate 150d is a transparent material such as glass or plastic. In this embodiment, a light L emitted by an organic layer 130d emits light through the second electrode 120d (i.e. a light emitting direction D1) and through a conductive layer 140d, the first electrode 110d, and the substrate 150d (i.e. a light emitting direction D2). In short, the light emitting device 100d of this embodiment is a double-sided light emitting device. In addition, because the light emitting device 100d of this embodiment is provided with the conductive layer 140d, an energy radiated by the light L emitted by the organic layer 130d through the first electrode 110d is less than an energy radiated by the light L emitted by the organic layer 130d through the second electrode 120d. In other words, light extraction efficiency achieved through the light emitting direction D1 is better than light extraction efficiency achieved through the light emitting direction D2.

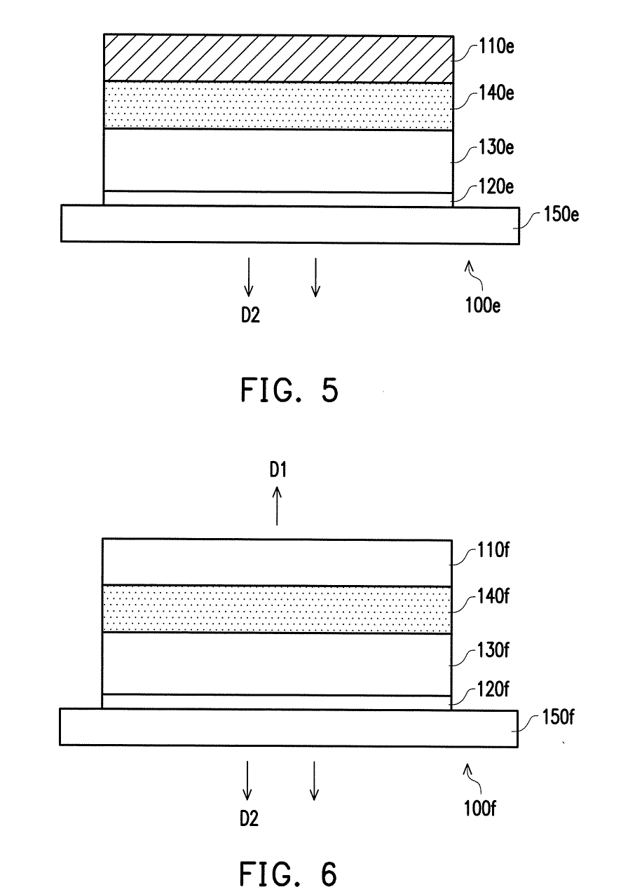

FIG. 5 illustrates a schematic sectional view of a light emitting device according to another embodiment of the disclosure. Please refer to FIG. 1 and FIG. 5 simultaneously. A light emitting device 100e in this embodiment is similar to the light emitting device 100a of FIG. 1. The differences between the two devices are a stacking sequence of components and material selection for a second electrode 120e. In this embodiment, a material of the second electrode 120e is a transparent conductive material, and the second electrode 120e, an organic layer 130e, a conductive layer 140e, and a first electrode 110e are sequentially stacked on a substrate 150e. Here, the substrate 150e is a transparent material such as glass or plastic. Therefore, the light emitting device 100e emits light toward a direction of the substrate 150e (i.e. a light emitting direction D2).

FIG. 6 illustrates a schematic sectional view of a light emitting device according to another embodiment of the disclosure. Please refer to FIG. 5 and FIG. 6 simultaneously. A light emitting device 100f in this embodiment is similar to the light emitting device 100e of FIG. 5. The difference between the two devices is material selection for a first electrode 110f. In this embodiment, materials of the first electrode 110f and a second electrode 120f are both transparent conductive materials, and the second electrode 120f, an organic layer 130f, a conductive layer 140f, and the first electrode 110f are sequentially stacked on a substrate 150f. Therefore, the light emitting device 100f emits light toward the first electrode 110f (i.e. a light emitting direction D1) and toward the second electrode 120f (i.e. a light emitting direction D2). In short, the light emitting device 100f of this embodiment is a double-sided light emitting device. In addition, because the light emitting device 100f of this embodiment is provided with the conductive layer 140f, an energy radiated through the first electrode 110f is less than an energy radiated through the second electrode 120f. In other words, light extraction efficiency achieved through the light emitting direction D2 is better than light extraction efficiency achieved through the light emitting direction D1.

In summary of the above, the light emitting device of the embodiment of this disclosure is provided with the conductive layer, and here the refractive index of the conductive layer is lower than the refractive index of the organic layer in the visible light wavelength, so that the energy radiated by the light emitted by the organic layer through the first electrode is less than the energy radiated by the light emitted by the organic layer through the second electrode. Therefore, in this disclosure, by providing the conductive layer to the light emitting device, a light energy loss that occurs between excitons and an interface of the electrode is reduced such that light extraction efficiency of the light emitting device is enhanced.

Although the embodiments are already disclosed as above, these embodiments should not be construed as limitations on the scope of this disclosure. It will be apparent to those ordinarily skilled in the art that various modifications and variations can be made to the disclosed embodiments without departing from the spirit or scope of the disclosure. In view of the foregoing, it is intended that the disclosure covers modifications and variations provided that they fall within the scope of the following claims and their equivalents.

What is claimed is:

1. A light emitting device, comprising:
a first electrode;
a second electrode;
an organic layer disposed between the first electrode and the second electrode; and
a conductive layer disposed between the organic layer and the first electrode, wherein a refractive index of the conductive layer is lower than a refractive index of the organic layer in a visible light wavelength, so that an energy radiated by a light emitted by the organic layer through the first electrode is less than an energy radiated by the light emitted by the organic layer through the second electrode.

2. The light emitting device as recited in claim 1, further comprising:
a substrate, on which the first electrode, the second electrode, the organic layer, and the conductive layer are disposed.

3. The light emitting device as recited in claim 2, wherein the first electrode, the conductive layer, the organic layer, and the second electrode are sequentially stacked on the substrate.

4. The light emitting device as recited in claim 2, wherein the second electrode, the organic layer, the conductive layer, and the first electrode are sequentially stacked on the substrate.

5. The light emitting device as recited in claim 2, wherein the substrate comprises a carrier substrate or an active element array substrate.

6. The light emitting device as recited in claim 1, wherein a material of the first electrode comprises metal, a transparent conductive material, or a combination thereof.

7. The light emitting device as recited in claim 1, wherein a refractive index of the first electrode is in a range of 0.1 to 5.0 in the visible light wavelength.

8. The light emitting device as recited in claim 1, wherein a material of the second electrode comprises metal, a transparent conductive material, or a combination thereof.

9. The light emitting device as recited in claim 1, wherein a refractive index of the second electrode is in a range of 0.1 to 5.0 in the visible light wavelength.

10. The light emitting device as recited in claim 1, wherein the refractive index of the organic layer is in a range of 1.2 to 2.5 in the visible light wavelength.

11. The light emitting device as recited in claim 1, wherein a thickness of the conductive layer is in a range of 30 nanometers to 200 nanometers.

12. The light emitting device as recited in claim 1, wherein the refractive index of the conductive layer is in a range of 1.1 to 1.7 in the visible light wavelength.

13. The light emitting device as recited in claim 1, wherein a material of the conductive layer comprises a transparent conductive organic compound, a transparent conductive inorganic compound, or a combination thereof.

14. The light emitting device as recited in claim 1, further comprising:
a buffer layer disposed between the first electrode and the conductive layer.

15. The light emitting device as recited in claim 1, further comprising:
a cover layer, wherein the second electrode is disposed between the cover layer and the organic layer.
